(19) United States
(12) Patent Application Publication
(10) Pub. No.: US 2022/0115251 A1
(43) Pub. Date: Apr. 14, 2022

(54) REPAIR DEVICE FOR DISPLAY PANEL

(71) Applicant: TCL CHINA STAR OPTOELECTRONICS TECHNOLOGY CO., LTD., Shenzhen, Guangdong (CN)

(72) Inventors: Wei ZHANG, Shenzhen (CN); Minggang LIU, Shenzhen (CN); Yang SUN, Shenzhen (CN); Shujhih CHEN, Shenzhen (CN)

(73) Assignee: TCL CHINA STAR OPTOELECTRONICS TECHNOLOGY CO., LTD., Shenzhen, Guangdong (CN)

(21) Appl. No.: 16/764,900

(22) PCT Filed: Apr. 22, 2020
(86) PCT No.: PCT/CN2020/086037

§ 371 Date: May 18, 2020

(30) Foreign Application Priority Data
Apr. 3, 2020 (CN) 202010257641.0

(51) Int. Cl. H01L 21/67

(52) U.S. Cl. CPC H01L 21/67144; H01L 25/0753; H01L 21/67288

(57) ABSTRACT

The application provides a repair device for a display panel, including: a defect sensor configured to obtain defect information; a chip pick-and-place part configured to pick up, store, and release light-emitting chips, wherein the chip pick-and-place part includes a chip storage cavity and a controller, the chip storage cavity is used to store the light-emitting chips, and the controller is configured to pick up and release a chip; a chip moving part connected to the chip pick-and-place part for moving the chip pick-and-place part to positions where defects are located according to the defect information; and a chip bonding part.

### FIELD OF INVENTION

The present application relates to the field of display, and in particular to a repair device for a display panel.

### BACKGROUND OF INVENTION

Micro light-emitting diodes (micro LEDs) have advantages of high brightness, great luminous efficiency, low power consumption, long service life, thinness and lightness, and the like. It is expected to become a next-generation mainstream display technology. A manufacturing method of the micro LEDs is mainly arranging LEDs with a few micrometers to several tens of micrometers in an array on a substrate to form an LED array with high density and small size. However, a lighting yield of micro LED display devices manufactured by mass transfer still cannot meet a technical requirement of 99.9999% in a mass production stage. Therefore, a display panel needs to be repaired after the transfer process is completed. In a repair process, different process fixtures need to be prepared for substrates with different specifications of pixels, resulting in problems such as complicated processes and long working hours.

### Technical Problem

In view of this, the purpose of the present application is to provide a repair device for a display panel that can simplify the manufacturing process and shorten working hours.

### SUMMARY OF INVENTION

This application provides a repair device for a display panel, which includes: a defect sensor configured to inspect defects of the display panel to obtain defect information; a chip pick-and-place part configured to pick up, store, and release light-emitting chips, the chip pick-and-place part including a chip storage cavity and a controller, wherein the chip storage cavity is used to store the light-emitting chips, and the controller is configured to pick up and release a chip; a chip moving part connected to the chip pick-and-place part for moving the chip pick-and-place part to positions where the defects are located according to the defect information; and a chip bonding part configured to bond the light-emitting chips to the display panel.

In one embodiment, the chip storage cavity includes a cavity extending along a first direction, and the chip storage cavity is used for stacking the light-emitting chips in the chip storage cavity.

In one embodiment, the cavity is a cylindrical cavity, and the first direction is parallel to a central axis of the cylindrical cavity.

In one embodiment, the repair device for a display panel includes a plurality of chip pick-and-place parts, and each of the chip pick-and-place parts is used to store the light-emitting chips of one color.

In one embodiment, the repair device for a display panel includes a plurality of chip pick-and-place parts, and each of the chip pick-and-place parts is used to store the light-emitting chips of multiple colors.

In one embodiment, the chip pick-and-place part is configured to pick up and store at least one of the light-emitting chips and release the light-emitting chips one by one at the positions where the defects are located.

In one embodiment, the controller includes a chip pick-up part for picking up the light-emitting chips, the chip pick-up part includes one or more of an electromagnetic force pick-up component, an electrostatic force pick-up component, and a vacuum suction pick-up component.

In one embodiment, the controller includes a chip releasing part for releasing the light-emitting chips at the positions where the defects are located, the chip releasing part includes one or more of a pressure releasing component, an electrostatic force releasing component, an electromagnetic force releasing component, and a fluid releasing component.

In one embodiment, the controller includes a chip pick-up part for picking up the light-emitting chips and a chip releasing part for releasing the light-emitting chips at the positions where the defects are located. The chip pick-up part includes one or more of an electromagnetic force pick-up component, an electrostatic force pick-up component, and a vacuum suction pick-up component. The chip releasing part includes one or more of a pressure releasing component, an electrostatic force releasing component, an electromagnetic force releasing component, and a fluid releasing component.

In one embodiment, the chip pick-up part and the chip releasing part are the same components.

In one embodiment, the chip pick-up part and the chip releasing part are provided separately.

In one embodiment, the controller includes a chip pick-up part for picking up the light-emitting chips and a chip releasing part for releasing the light-emitting chips at the positions where the defects are located, the chip pick-up part and the chip releasing part are the same components.

In one embodiment, the defect information includes positions, numbers, and colors of the defects.

In one embodiment, the chip bonding part includes one or more of a reflow bonding component and a thermo-compression bonding component.

### Beneficial Effect

Compared with the prior art, the repair device for a display panel of the present application collects and stores the micro LED light-emitting chips used for performing defect repair in the chip pick-and-place part, and according to the defect information obtained by scanning the display panel, the light-emitting chips are released and bound at the defect locations. This can achieve the beneficial effects of simplifying the repair process and shortening the working hours.

### DESCRIPTION OF DRAWINGS

In order to more clearly explain the technical solutions in the present application, the following will briefly introduce the drawings required in the description of the implementation manner. Obviously, the drawings in the description are only some embodiments of the present application. Those skilled in the art can obtain other drawings based on these drawings without paying any creative work.

FIG. 1 is a schematic plan view of a display panel with defects provided by the present application.

FIG. 2 is a schematic diagram of a repair device for a display panel provided by the present application for repairing a defective display panel.

FIG. 3 is a schematic diagram of a circular light-emitting chip provided by the present application.

FIG. 4 is a block diagram of a controller provided by the present application.

### DETAILED DESCRIPTION OF PREFERRED EMBODIMENTS

The technical solutions in the present application will be described clearly and completely together with the drawings in the embodiments of the present application. Obviously, the described embodiments are only a part of the embodiments of the present application, but not all the embodiments. Based on these embodiments in the present application, all other embodiments obtained by those skilled in the art without making creative work fall within the protection scope of the present application.

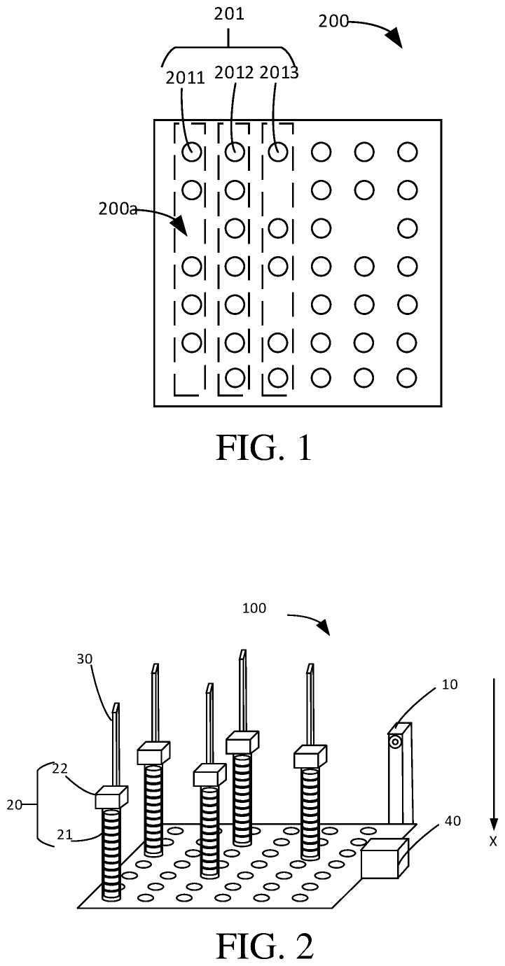

Please refer to FIG. 1 and FIG. 2, the first embodiment of the present application provides a repair device 100 for a display panel, which is used to repair defects of a display panel 200 having a defect 200a. The display panel 200 is a micro light-emitting diode (micro LED) display panel. The display panel 200 includes a plurality of light-emitting chips 201. The multiple light-emitting chips 201 are arranged in an array. The light-emitting chips 201 can all be blue light-emitting chips or can be light-emitting chips of different colors, such as red, green, and blue light-emitting chips. In this embodiment, the light-emitting chip 201 includes a first light-emitting chip 2011, a second light-emitting chip 2012, and a third light-emitting chip 2013. The first light-emitting chip 2011, the second light-emitting chip 2012 and the third light-emitting chip 2013 respectively emit different colors of light. The first light-emitting chip 2011, the second light-emitting chip 2012, and the third light-emitting chip 2013 are arranged in a row in this order. The display panel 200 has the defect 200a. The defect 200a means that the micro LED was not successfully transferred during the manufacturing process or could not be lit after the transfer, resulting in the display panel 200 failing to be lit and requiring a light-emitting chip supplement.

The repair device 100 for a display panel includes a defect sensor 10, which is used to perform defect inspection on the display panel 200 to obtain defect information; a chip pick-and-place part 20 configured to pick up, store, and release light-emitting chips 201, wherein the chip pick-and-place part 20 includes a chip storage cavity 21 and a controller 22, the chip storage cavity 21 is used to store the light-emitting chips 201, and the controller 22 is configured to pick up and release a chip 201; a chip moving part 30 connected to the chip pick-and-place part 20 for moving the chip pick-and-place part 20 to positions where the defect 200a is located according to the defect information; and a chip bonding part 40 configured to bond the light-emitting chips 201 to the display panel 200.

The defect sensor 10 is used for performing directed addressing of the defect 200a. For example, the defect sensor 10 can be a camera. When the display panel 200 is lit, the defect sensor 10 inspects the display panel 200 to obtain defect information. The defect information includes a location, number, and color of defects, which are coordinates, number, and colors of the light-emitting chips 201 that need to be supplemented.

The repair device 100 for a display panel may include one or more chip pick-and-place part 20. Each of the plurality of chip pick-and-place part 20 is used to store a light-emitting chip 201 of one color. The chip storage cavity 21 includes a cavity extending along the first direction X, and the chip storage cavity 21 is used for the light-emitting chips 201 to be stacked therein. The structure of the light-emitting chip 201 is not limited in this application, and it can be a front-mounted structure chip, a vertical-structure chip, or a flip-chip structure chip.

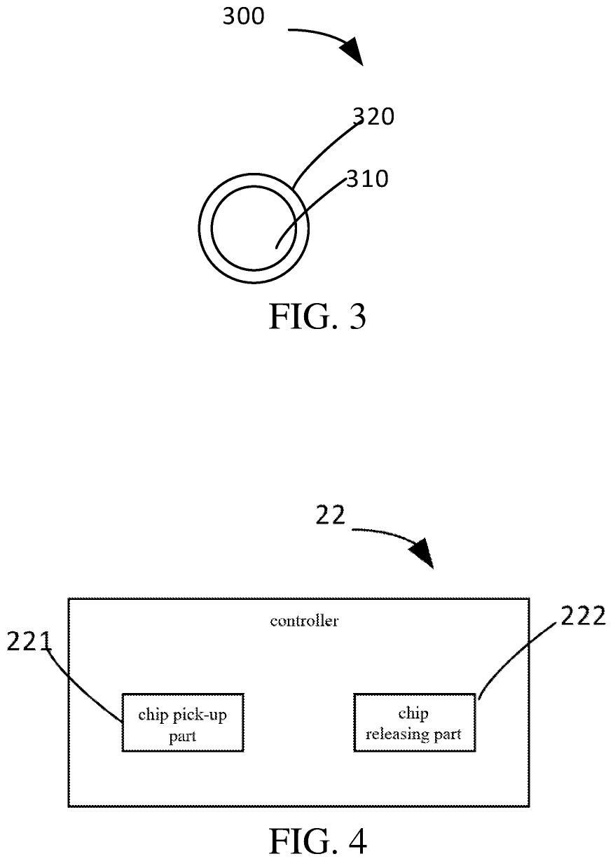

The repair device 100 for a display panel can include one or more chip pick-and-place parts 20. Each of the plurality of chip pick-and-place parts 20 is used to store a light-emitting chip 201 of one color. The chip storage cavity 21 has a cavity extending along the first direction X. The chip storage cavity 21 is used for the light-emitting chip 201 to be stacked and arranged therein. The structures of the light-emitting chips 201 are not limited in this application, they can be a front-mounted structured chip, a vertical-structure chip, or a flip-chip structured chip. In a case of a flip-chip structure, the cavity can be a cylindrical cavity, and the first direction X is parallel to the central axis of the cylindrical cavity. Please refer to FIG. 3, the circular light-emitting chip 300 includes an inner circle 310 and an outer ring 320 surrounding the inner circle 310. Two electrodes (i.e. the positive electrode and the negative electrode) of the circular light-emitting chip 300 are provided on the inner circle 310 and the outer ring 320, respectively. Therefore, it is not necessary to distinguish the two electrodes when picking up the circular light-emitting chip 300. The two electrodes of the rectangular light-emitting chip are respectively disposed on the left side and the right side thereof, and it is necessary to distinguish the two electrodes when picking up. Therefore, the cross-part of the chip storage cavity 21 is set to a circular shape, and the efficiency of picking up and releasing the circular light-emitting chips 300 can be improved. If the chip is a vertical structure chip, it is not subjected to the above limitation. The cross-part of the chip storage cavity 21 can be rectangular, circular, triangular, etc. The shape of the cavity can be adjusted according to the shape of the light-emitting chip 201, as long as it can match the shape of the light-emitting chip 201.

In addition, the chip pick-and-place part 20 is used to pick up and store at least one of the light-emitting chips 201 and release the light-emitting chips one by one at the positions where each of the defects 200a are located.

In another embodiment of the present application, one chip pick-and-place part 20 can also be used to store light-emitting chips 201 of multiple colors.

Please refer to FIG. 4, the controller 22 includes a chip pick-up part 221 for picking up light-emitting chips and a chip releasing part 222 for releasing the light-emitting chips at a position where the defect is located. The controller 22 can pick up the light-emitting chips 201 from a wafer or a temporary substrate on which the light-emitting chips 201 are placed and store them in the chip storage cavity 21. The chip pick-up part 221 and the chip releasing part 222 can be provided separately or can be formed integrally. That is, the chip pick-up part 221 and the chip releasing part 222 can be the same component. The chip pick-up part 221 can include one or more of an electromagnetic force pick-up component, an electrostatic force pick-up component, and a vacuum suction pick-up component. The chip releasing part 222 can include one or more of a pressure releasing component, an electrostatic force releasing component, an electromagnetic force releasing component, and a fluid releasing component.

The chip moving part 30 may include components such as slide rails for moving the chip pick-up part 221. The chip bonding part 40 may include one or more of a reflow bonding component and a thermo-compression bonding component. The chip bonding part 40 is used to perform a reflow soldering or thermo-compression bonding process of chips on the entire surface of the display panel 200 when the chip pick-and-place part 20 places the light-emitting chip 201 at the position of the defect 200a to complete the repair operation.

In the process of repairing the display panel 200, when the display panel 200 is lit, the defect sensor 10 inspects the display panel 200, obtains defect information, and transmits the information to the controller (not shown). The controller 22 controls the chip pick-and-place part 20 to pick up and collect the light-emitting chips 201 according to the defect information and store them in the chip storage cavity 21. It can be understood that the chip pick-and-place part 20 may store the light-emitting chips 201 in advance. The chip moving part 30 moves the chip pick-and-place part 20 to a position where the defect 200a of the light-emitting chips 201 needs to be supplemented. At this time, the cavity 20a of the chip pick-and-place part 20 is perpendicular to the display surface of the display panel 200. After alignment, the chip pick-and-place part 20 releases the light-emitting chip 201. The chip bonding part 40 then performs a reflow soldering or thermo-compression bonding process on the entire surface of the display panel 200.

Compared with the prior art, the repair device for a display panel of the present application collects and stores the micro LED light-emitting chips used for repairing defects in the chip pick-and-place part, and according to the defect information obtained by scanning and inspecting the display panel, the light-emitting chip is released and bound at the defect location. The beneficial effects of simplifying the repairing process and shortening working hours can be achieved.

The above description provides a detailed introduction to the implementation of the present application. In the description, specific examples are used to explain the principles and implementation of the present application. The description of the embodiment is only used to help understand the present application. In addition, for those skilled in the art, according to the ideas of the present application, there will be changes in the specific implementation manner and application scope. Therefore, the content of the specification should not be construed as limiting the application.

What is claimed is:

1. A repair device for a display panel, comprising:
a defect sensor configured to inspect defects of the display panel to obtain defect information;
a chip pick-and-place part configured to pick up, store, and release light-emitting chips, the chip pick-and-place part comprising a chip storage cavity and a controller, wherein the chip storage cavity is used to store the light-emitting chips, and the controller is configured to pick up and release a chip;
a chip moving part connected to the chip pick-and-place part for moving the chip pick-and-place part to positions where the defects are located according to the defect information; and
a chip bonding part configured to bond the light-emitting chips to the display panel.

2. The repair device for the display panel according to claim 1, wherein the chip storage cavity comprises a cavity extending along a first direction, and the chip storage cavity is used for stacking the light-emitting chips in the chip storage cavity.

3. The repair device for the display panel according to claim 2, wherein the chip pick-and-place part is configured to pick up, store, and release a flip-chip structure, the cavity is a cylindrical cavity, and the first direction is parallel to a central axis of the cylindrical cavity.

4. The repair device for the display panel according to claim 1, further comprising a plurality of chip pick-and-place parts, and each of the chip pick-and-place parts is used to store the light-emitting chips of one color.

5. The repair device for the display panel according to claim 1, further comprising a plurality of chip pick-and-place parts, and each of the chip pick-and-place parts is used to store the light-emitting chips of multiple colors.

6. The repair device for the display panel according to claim 1, wherein the chip pick-and-place part is configured to pick up and store at least one of the light-emitting chips and release the light-emitting chips one by one at the positions where the defects are located.

7. The repair device for the display panel according to claim 1, wherein the controller comprises a chip pick-up part for picking up the light-emitting chips, and the chip pick-up part comprises one or more of an electromagnetic force pick-up component, an electrostatic force pick-up component, and a vacuum suction pick-up component.

8. The repair device for the display panel according to claim 1, wherein the controller comprises a chip releasing part for releasing the light-emitting chips at the positions where the defects are located, and the chip releasing part comprises one or more of a pressure releasing component, an electrostatic force releasing component, an electromagnetic force releasing component, and a fluid releasing component.

9. The repair device for the display panel according to claim 1, wherein the controller comprises a chip pick-up part for picking up the light-emitting chips and a chip releasing part for releasing the light-emitting chips at the positions where the defects are located, the chip pick-up part comprises one or more of an electromagnetic force pick-up component, an electrostatic force pick-up component, and a vacuum suction pick-up component, and the chip releasing part comprises one or more of a pressure releasing component, an electrostatic force releasing component, an electromagnetic force releasing component, and a fluid releasing component.

10. The repair device for the display panel according to claim 1, wherein the chip pick-up part and the chip releasing part are same components.

11. The repair device for the display panel according to claim 1, wherein the chip pick-up part and the chip releasing part are provided separately.

12. The repair device for the display panel according to claim 1, wherein the controller comprises a chip pick-up part for picking up the light-emitting chips and a chip releasing part for releasing the light-emitting chips at the positions where the defects are located, and the chip pick-up part and the chip releasing part are same components.

13. The repair device for the display panel according to claim 1, wherein the defect information comprises positions, numbers, and colors of the defects.

14. The repair device for the display panel according to claim 1, wherein the chip bonding part comprises one or more of a reflow bonding component and a thermo-compression bonding component.
